(19) United States
(12) Patent Application Publication
(10) Pub. No.: US 2006/0194389 A1
(43) Pub. Date: Aug. 31, 2006

(54) Method for fabricating flash memory device

(75) Inventors: Cha Deok Dong, Kyeongki-do (KR); Jae Soon Kwon, Chungcheongbuk-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 11/292,461

(22) Filed: Dec. 2, 2005

(30) Foreign Application Priority Data
Feb. 28, 2005 (KR) 10-2005-0016433

(51) Int. Cl. H01L 21/336

(52) U.S. Cl. 438/257

(57) ABSTRACT

A method is provided for fabricating a flash memory device, preventing particles from spreading around edges of a wafer while pre-cleaning a tunnel oxide film by removing particles at the edges of the wafer. Accordingly, it is able to overcome the problems arising from quality deterioration of the tunnel oxide film and defective patterns.

### BACKGROUND OF THE INVENTION

The present invention relates to methods for fabricating flash memory devices and more particularly, to a method for fabricating a flash memory device improving the quality of a tunnel oxide film and a device profile.

A general flash memory device is fabricated through the process of: (a) forming laser masks; (b) screening a threshold voltage; (c) masking and etching pre-keys; (d) implanting ionic impurities for wells and threshold voltages; (e) forming a pad nitride film and a capping oxide film; (f) forming high-voltage fields after completely removing the capping oxide film; (g) completely removing the pad nitride film to open low-voltage fields; (h) pre-cleaning the wafer; and (i) entirely oxidizing the wafer to form a tunnel oxide film in the low-voltage fields, and to form a gate oxide film thicker than the tunnel oxide film by the thickness of the oxide film, in the high-voltage fields.

As many masking and etching steps need to be carried out before forming the tunnel oxide film, particles are generated at edges of the wafer substrate. These particles may float and flow into the wafer substrate during the pre-cleaning of the wafer with the tunnel oxide film.

The ingredients of such particles are heavily composed of carbonic impurities, which degrade the quality of the tunnel oxide film. Further, the particles generate defects (e.g., protruding profiles) that influence subsequent patterns, decreasing product yield.

### BRIEF SUMMARY OF THE INVENTION

The present invention provides a method for fabricating a flash memory device that improves the quality of a tunnel oxide film.

The present invention provides a method for fabricating a flash memory device that improves a product yield by preventing defects due to particles.

One aspect of the present invention is a method for fabricating a flash memory device, the method comprising the steps of: (a) forming an oxide film in a high-voltage region of a wafer substrate including a first low-voltage region and the high-voltage region; (b) removing particles from edges parts of the wafer substrate; (c) pre-cleaning the wafer substrate; and (d) forming a tunnel oxide film with a first thickness in the low-voltage region, and a gate oxide film which has a second thickness larger than the first thickness by the thickness of the oxide film in the high-voltage region.

Step (b) is a process for etching the edge parts of the wafer substrate slantwise, e.g., to provide a sloping edge profile.

The edge parts of the wafer substrate are located within 2˜3 mm from the edges of the wafer substrate.

The slant etching process is carried out in an atmosphere of a gas mixed with CF₄ and Ar.

The CF₄ is supplied in a flow rate of 100˜200 sccm while the Ar is supplied at a flow rate of 50˜100 sccm.

The slant etching process is carried out under a PF power of 50˜200 W.

Step (b) reduces the edge parts of the wafer substrate by a thickness of 20˜50 Å, clearing particles absorbed on the wafer substrate.

The step (c) uses SC-1 (NH₄OH+H₂O₂+H₂O) and a diluted HF solution in sequence.

Step (a) is comprised of: forming a pad nitride film and a capping oxide film on the aforementioned wafer substrate; forming a mask to open the high-voltage field on the capping oxide film; removing the capping oxide film and the pad nitride film using the mask, providing the wafer substrate in the high-voltage field; completely removing the capping oxide film; forming the oxide film in the high-voltage field using the pad nitride film as a mask; and completely removing the pad nitride film.

The method further comprises forming a screen oxide film over the wafer substrate before forming the oxide film in step (a).

The screen oxide film is formed in a thickness of 50˜80 Å.

Step (d) comprises: forming the oxide film with a predetermined thickness in temperature of 750˜800° C.; and expanding the oxide film to a predetermined thickness through an annealing process with N₂O gas in temperature of 900˜1000° C., forming the tunnel oxide film in the low-voltage field and the gate oxide film in the high-voltage field.

Step (d) the tunnel oxide film is formed to contain 2.0˜3.0% of nitrogen.

### BRIEF DESCRIPTION OF THE DRAWINGS

The accompanying drawings are included to provide further understanding of the invention, and are incorporated in, and constitute part of, this specification. The drawings illustrate exemplary embodiments of the present invention and, together with the description, serve to explain principles of the present invention. In the drawings:

FIGS. 1A-1E are sectional views illustrating steps for a process of fabricating a flash memory device in accordance with an embodiment of the present invention.

### DETAILED DESCRIPTION OF THE INVENTION

Preferred embodiments of the present invention will be described below in more detail with reference to the accompanying drawings. The present invention may, however, be embodied in different forms, and should not be constructed as limited to the embodiments set forth herein. Rather, these embodiments are provided so that this disclosure will be thorough and complete, and will fully convey the scope of the invention to those skilled in the art. Like numerals refer to like elements throughout the specification.

Hereinafter, an exemplary embodiment of the present invention will be described in conjunction with the accompanying drawings.

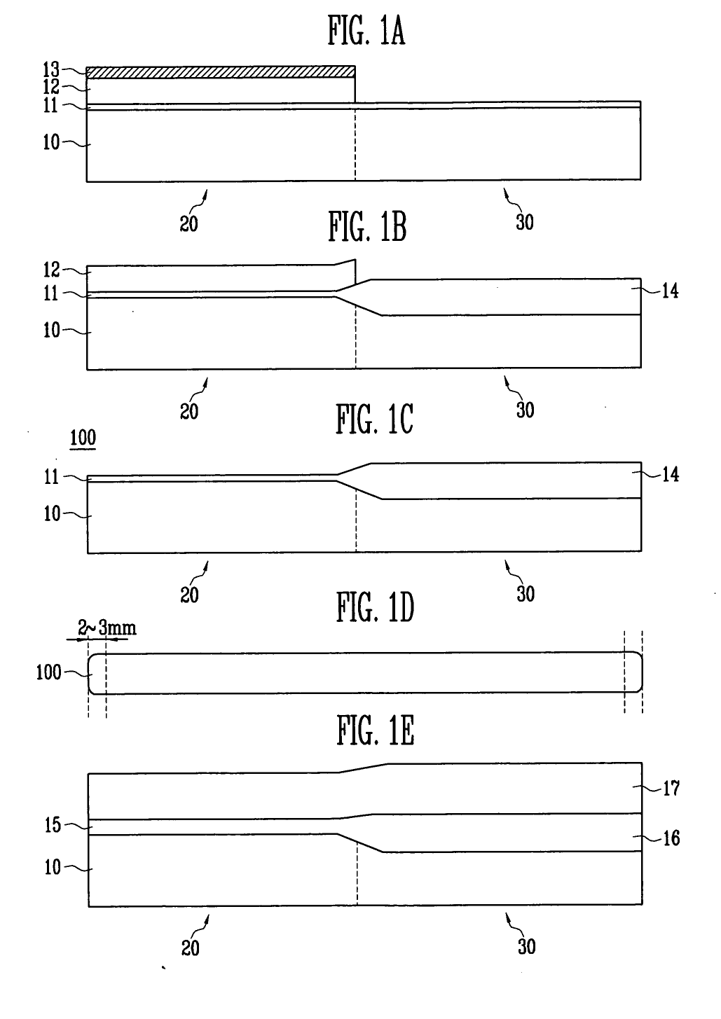

FIGS. 1A through 1E are sectional views illustrating processing steps for fabricating a flash memory device in accordance with an embodiment of the invention. FIGS. 1A, 1B, 1C and 1E show a portion of the wafer in FIG. 1D.

First, as illustrated FIG. 1A, a screen oxide film 11 is formed over a wafer or substrate 10, in which a laser masking process has been completed, by means of a dry or wet oxidation process. The substrate includes one or more low-voltage regions 20 and one or more high-voltage regions 30. Low-wattage transistors are formed on the low-voltage region 20, and high voltage transistors are formed on the high-voltage region 30.

The screen oxide film 11 is formed at a thickness of 50˜80 Å, which includes the amount that would be eroded by the masking and PR striping/cleaning process for ion implantation of a well, and threshold voltage thereafter.

Then, a pre-key masking and etching process is conducted, as well as the ion implantation for a well and threshold voltage control.

Thereafter, a pad nitride film 12 and a capping oxide film 13 are deposited in sequence. It is preferable for the capping oxide film 13 to be made of a high-temperature oxide (HTO) film.

After the HV recess HRC mask (not shown) is formed on the capping oxide film 13 to open a high-voltage field, the capping oxide film 13 and the pad nitride film 12 are removed by using the HRC mask, and the HRC mask is stripped therefrom.

In order to prevent the generation of defects on the junction between the capping oxide film 13 and the HRC mask, it is preferable to perform a cleaning process with PIRANHA (H₂SO₄+H₂O₂) before forming the HRC mask.

Then, as illustrated in FIG. 1B, after completely removing the capping oxide film 13, an oxidation is carried out with a mask by the pad nitride film 12 remaining on the low-voltage region, resulting in an oxide film 14 with a first thickness in the high-voltage region. The oxide film 14 is provided to be sufficiently thick to handle high-voltage transistors to be formed thereon.

Next, as illustrated in FIG. 1C, the pad nitride film 12 is completely removed from the low-voltage region.

After carrying out the above processing steps, particles may have accumulated significantly at edges of the wafer 10. When the particles float and flow into the wafer 10 during the subsequent pre-cleaning process for the tunnel oxide film, quality degradation of the tunnel oxide film and defects of projection on the profile may result.

Thus, as shown in FIG. 1D, a slant etching process is carried out to remove the oxide or nitride particles, which are located within 2˜3 mm from the edges 100 (on outer portions) of the wafer and part of the wafer 10 by a predetermined thickness of 20˜50 Å, so that the particles deposited on and absorbed into the wafer 10 are etched away to prevent the particle contamination therein.

The slant etching process is carried out in an atmosphere of the mixed gasses CF₄ and Ar, adjusting RF power to minimize damages to regions of the tunnel oxide film.

The CF₄ gas is supplied thereto with a flow rate of 100˜200 sccm while the Ar gas is supplied with a flow rate of 50˜100 sccm, while applying the RF power of 50˜200 W that is not too high to minimize plasma damages to the tunnel oxide film.

Then, SC-1 (NH₄OH+H₂O₂+H₂O) and a diluted HF solution are used in sequence to conduct the pre-cleaning process for the tunnel oxide film, further removing organic materials remaining therein and removing natural oxide films at the regions of the tunnel oxide film.

Since much of the particles were removed from the edges 100 of the wafer by the slant etching process, the amount of the particles flowing into the wafer 10 is reduced significantly.

Thereafter, an overall oxidation process is carried out to deposit the tunnel oxide film 15 in a low-voltage region. A gate oxide film 16 is obtained in the high-voltage region. The gate oxide film 16 is thicker than the tunnel oxide film 15 by the thickness of the oxide film 14. That is, the thickness of the oxide film 16 is the combined thicknesses of the film 14 and film 15.

In the overall oxidation, after depositing or growing a pure oxide film to a given thickness at the temperature of 750˜800° C., the tunnel oxide film 15 is then annealed and formed to a desired thickness using N₂O gas of good quality at 900˜1000° C., with nitrogen content in the range of 2.0˜3.0%. The oxide film 15 is sufficiently thin to be used with low-voltage transistors to be formed thereon.

Next, a polysilicon film 17 is deposited on the tunnel oxide film 15 and the high-voltage gate oxide film 16. Then a trench field isolation film is formed by a self-aligned shallow trench isolation (STI) process.

While the above embodiment is described as employing the self-aligned STI process, other process methods may be used.

First, the present invention prevents the quality deterioration of tunnel oxide film by preliminarily removing particles from the edges of the wafer through the slant etching process.

Second, it is possible to minimize the damages on the regions of the tunnel oxide film and to enhance the efficiency of removing the particles by controlling the RF power during the slant etching process.

Third, it is able to prevent the profile defects due to the particles.

Fourth, it is possible to reduce defects due to the particles, improving a product yield of the flash memory device.

Although the present invention has been described in accordance with the embodiment of the present invention illustrated in the accompanying drawings, it is not limited thereto. It will be apparent to those skilled in the art that various substitutions, modifications, and changes may be made thereto without departing from the scope of the invention.

What is claimed is:

1. A method for fabricating a flash memory device, the method comprising:
forming an oxide film in a high-voltage region of a wafer, the substrate including a first low-voltage region and the high-voltage region;
removing particles from outer portions of the wafer using an etch process;
pre-cleaning the wafer; and
forming a tunnel oxide film with a first thickness in the low-voltage region and a gate oxide film, with a second thickness in the high-voltage field, the second thickness being greater than the first thickness by the thickness of the oxide film.

2. The method as set forth in claim 1, wherein the outer portions of the wafer are etched to provide edges of the wafer with sloping profiles.

3. The method as set forth in claim 1, wherein the outer portions of the wafer are located within 2˜3 mm from the outermost edges of the wafer.

4. The method as set forth in claim 2, wherein the etching is performed with a gas mixture that includes CF₄ and Ar.

5. The method as set forth in claim 4, wherein the CF₄ is supplied in a flow rate of 100˜200 sccm while the Ar is supplied in a flow rate of 50˜100 sccm.

6. The method as set forth in claim 2, wherein the etching is performed with RF power of 50˜200 W.

7. The method as set forth in claim 1, wherein the etch process removes the edge parts of the wafer by a thickness of 20˜50 Å from the outer portions of the wafer to remove particles formed on or absorbed into the wafer.

8. The method as set forth in claim 1, wherein the pre-cleaning step uses SC-1 (NH₄OH+H₂O₂+H₂O) and a diluted HF solution in sequence.

9. The method as set forth in claim 1, wherein the forming un-oxide-film step comprises:
forming a pad nitride film and a capping oxide film on the wafer;
patterning the capping oxide film and the pad nitride film to expose the high-voltage region, the patterned capping oxide film and pad nitride film provided over the low-voltage region;
removing the patterned capping oxide film;
forming the oxide film in the high-voltage field with using the pad nitride film as a mask on the low-voltage region; and
removing the patterned pad nitride film.

10. The method as set forth in claim 1, further comprising forming a screen oxide film over the wafer before forming the oxide film over the high-voltage region.

11. The method as set forth in claim 10, wherein the screen oxide film is formed to a thickness of 50˜80 Å.

12. The method as set forth in claim 1, wherein the step forming a tunnel oxide film comprises:
forming the tunnel oxide film to a predetermined thickness in temperature of 750˜800° C.; and
increasing the thickness of the tunnel oxide film to a predetermined thickness through an annealing process using N₂O gas in temperature of 900˜1000° C.

13. The method as set forth in claim 1, wherein the tunnel oxide film is formed to contain 2.0˜3.0% of nitrogen.
